(19) United States
(12) Patent Application Publication
(10) Pub. No.: US 2025/0176208 A1
(43) Pub. Date: May 29, 2025

(54) SEMICONDUCTOR DEVICE

(71) Applicant: UNITED MICROELECTRONICS CORP., Hsin-Chu City (TW)

(72) Inventors: Wen-Kai Lin, Yilan County (TW); Kuo-Hsing Lee, Hsinchu County (TW); Guan-Kai Huang, Tainan City (TW); Chih-Kai Kang, Tainan City (TW); Yung-Chen Chiu, Taichung City (TW); Sheng-Yuan Hsueh, Tainan City (TW); Yao-Jhan Wang, Tainan City (TW)

(73) Assignee: UNITED MICROELECTRONICS CORP., Hsin-Chu City (TW)

(21) Appl. No.: 18/403,681

(22) Filed: Jan. 3, 2024

(30) Foreign Application Priority Data
Nov. 28, 2023 (TW) 112145985

(51) Int. Cl. H01L 29/78; H01L 27/146; H01L 29/417; H01L 29/66; H01L 29/94

(52) U.S. Cl. CPC H10D 30/62; H10D 1/66; H10F 39/18; H10D 30/0241; H10D 30/6219

(57) ABSTRACT

A semiconductor device includes a semiconductor substrate of a first conductivity type; a well region of the first conductivity type in the semiconductor substrate; and a fin disposed on the semiconductor substrate within the well region. The fin extends along a first direction. The fin includes a first portion and a second portion that is contiguous with the first portion. The first portion includes a counter-doping region having dopants of a second conductivity type. A gate extends over the fin along a second direction. The gate overlaps with the first portion of the fin and does not overlap with the second portion of the fin.

### BACKGROUND OF THE INVENTION

### 1. Field of the Invention

The present invention relates to the field of semiconductor technology, and in particular to a metal-oxide-semiconductor (MOS) capacitor structure, which is suitable for use in image signal processor (ISP) devices and processes.

### 2. Description of the Prior Art

To be able to manufacture integrated circuits such as memories, logic devices and other components with higher integration densities, an improved method for further reductions in the size of capacitors (e.g. metal-oxide-semiconductor capacitors) and field effect transistors (e.g. metal-oxide-semiconductor field effect transistor) is needed. By reducing the overall size and operating voltage of the device while maintaining the electrical characteristics of the device, scaling can increase device density and improve device operation performance.

### SUMMARY OF THE INVENTION

It is one object of the present invention to provide an improved semiconductor device in order to solve the deficiencies or shortcomings of the existing technology.

One aspect of the invention provides a semiconductor device including a semiconductor substrate having a first conductivity type; a well region having the first conductivity type in the semiconductor substrate; a fin disposed on the semiconductor substrate within the well region, wherein the fin extends along a first direction, wherein the fin comprises a first portion and a second portion that is contiguous with the first portion, wherein the first portion comprises a counter-doping region having dopants of a second conductivity type; and a gate extending over the fin along a second direction, wherein the gate overlaps with the first portion of the fin and does not overlap with the second portion of the fin.

According to some embodiments, an insulating layer is disposed between the first portion of the fin and the gate, wherein the gate, the first portion, and the insulating layer constitute a metal-oxide-semiconductor capacitor.

According to some embodiments, the second portion of the fin does not include the dopants of the second conductivity type.

According to some embodiments, the first conductivity type is P type and the second conductivity type is N type.

According to some embodiments, the well region is a P well region, and wherein the first portion of the fin and the second portion of the fin are above the P well region.

According to some embodiments, the second portion of the fin comprises an epitaxial layer.

According to some embodiments, the epitaxial layer comprises a SiP epitaxial layer.

According to some embodiments, the epitaxial layer is contiguous with the counter-doping region in the first portion of the fin.

According to some embodiments, the gate is a metal gate.

According to some embodiments, the counter-doping region has a doping concentration of 1.5×10¹⁸-1.5×10²⁰ atoms/cm³.

Another aspect of the invention provides a semiconductor device including a semiconductor substrate having a first conductivity type; a fin disposed on the semiconductor substrate, wherein the fin extends along a first direction, wherein the fin comprises a first portion and a second portion that is contiguous with the first portion, wherein the first portion comprises a counter-doping region having dopants of a second conductivity type; and a gate extending over the fin along a second direction, wherein the gate overlaps with the first portion of the fin and does not overlap with the second portion of the fin.

According to some embodiments, an insulating layer is disposed between the first portion of the fin and the gate, wherein the gate, the first portion, and the insulating layer constitute a metal-oxide-semiconductor capacitor.

According to some embodiments, the second portion of the fin does not include the dopants of the second conductivity type.

According to some embodiments, the first conductivity type is P type and the second conductivity type is N type.

According to some embodiments, the fin is surrounded by a trench isolation structure, and wherein the first portion of the fin and the second portion of the fin are above the trench isolation structure.

According to some embodiments, the second portion of the fin comprises an epitaxial layer.

According to some embodiments, the epitaxial layer comprises a SiP epitaxial layer.

According to some embodiments, the epitaxial layer is contiguous with the counter-doping region in the first portion of the fin.

According to some embodiments, the gate is a metal gate.

According to some embodiments, the counter-doping region has a doping concentration of 1.5×10¹⁸-1.5×10²⁰ atoms/cm³.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a top view of a semiconductor device according to an embodiment of the present invention.

FIG. 2 is a schematic cross-sectional view taken along line I-I′ in FIG. 1.

FIG. 3 is a schematic cross-sectional view taken along line II-II′ in FIG. 1.

FIG. 4 is a top view of a semiconductor device according to another embodiment of the present invention.

FIG. 5 is a schematic cross-sectional view taken along line I-I′ in FIG. 4.

FIG. 6 is a schematic cross-sectional view taken along line II-II′ in FIG. 4.

### DETAILED DESCRIPTION

In the following detailed description of the disclosure, reference is made to the accompanying drawings, which form a part hereof, and in which is shown, by way of illustration, specific embodiments in which the invention may be practiced. These embodiments are described in sufficient detail to enable those skilled in the art to practice the invention.

Other embodiments may be utilized, and structural, logical, and electrical changes may be made without departing from the scope of the present invention. Therefore, the following detailed description is not to be considered as limiting, but the embodiments included herein are defined by the scope of the accompanying claims.

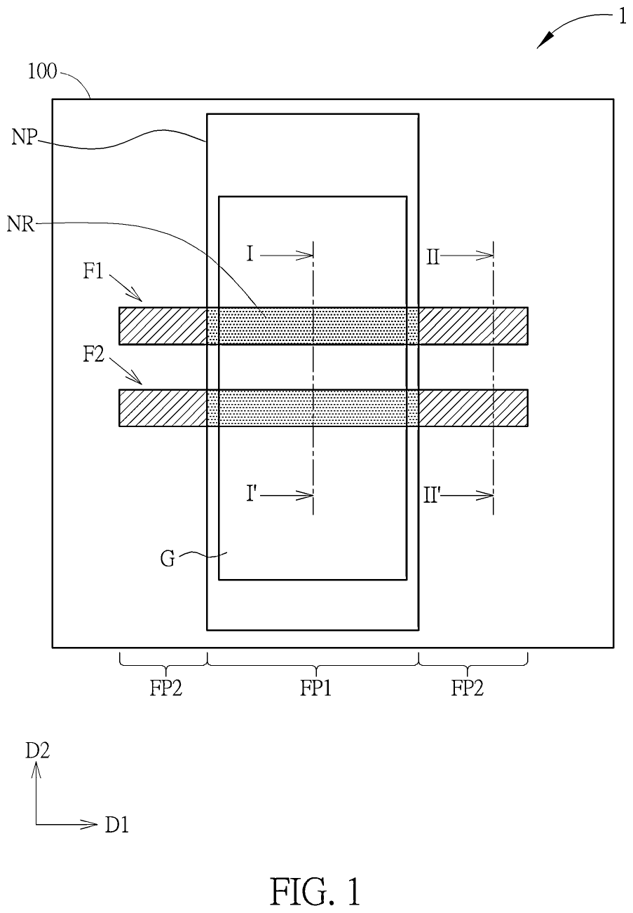

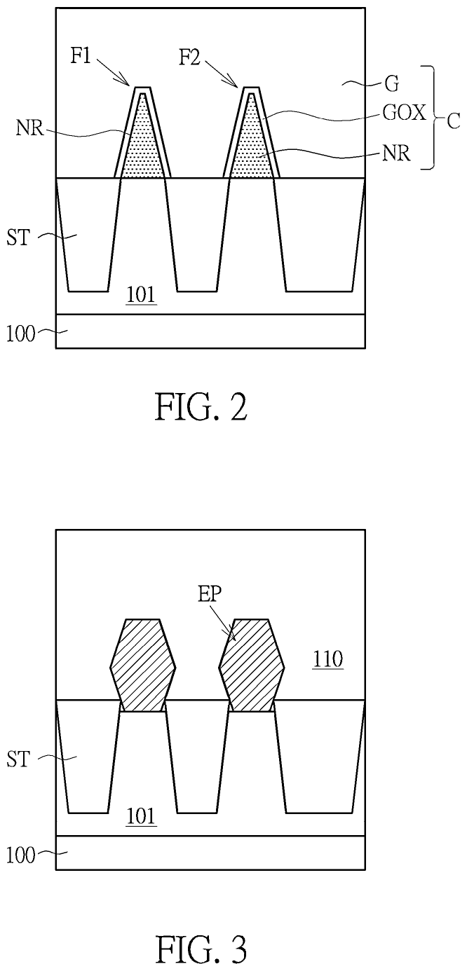

Please refer to FIGS. 1 to 3, wherein FIG. 1 is a top view of a semiconductor device according to an embodiment of the present invention, FIG. 2 is a schematic cross-sectional view taken along line I-I′ in FIG. 1, and FIG. 3 is a schematic cross-sectional view taken along the tangent line II-II′ in FIG. 1. As shown in FIG. 1 to FIG. 3, the semiconductor device 1, such as a metal-oxide-semiconductor (MOS) capacitor, includes a semiconductor substrate 100 with a first conductivity type. According to an embodiment of the present invention, the semiconductor substrate 100 may be, for example, a silicon substrate, but is not limited thereto. According to embodiments of the present invention, the first conductivity type may be, for example, P type.

According to an embodiment of the present invention, a well region 101 may be provided in the semiconductor substrate 100, wherein the well region 101 has a first conductivity type. According to embodiments of the present invention, the well region 101 may be, for example, a P-type well. According to embodiments of the present invention, for example, the semiconductor device 1 may be disposed within an NMOS transistor device region. Those familiar with this technical field should understand that there will be other semiconductor elements in the NMOS transistor device region, such as fin field effect transistors. For the sake of simplicity, these semiconductor elements are not shown in the figures.

According to an embodiment of the present invention, at least one fin, such as fins F1 and F2, is provided on the semiconductor substrate 100 in the well region 101. The fins F1 and F2 extend along a first direction D1. According to an embodiment of the present invention, the fins F1 and F2 protrude from the top surface of the trench isolation structure ST. According to an embodiment of the present invention, each of the fins F1 and F2 includes a first portion FP1 and a second portion FP2 that is contiguous with the first portion FP1. According to an embodiment of the present invention, the first portion FP1 directly contacts the second portion FP2. According to an embodiment of the present invention, the first portions FP1 of the fins F1 and F2 and the second portions FP2 of the fins F1 and F2 are located on the well region 101 (for example, a P-type well).

According to an embodiment of the present invention, the first portion FP1 includes a counter-doping region NR. According to an embodiment of the present invention, the counter-doping region NR is formed before forming the fins F1 and F2. An ion implantation region NP is first defined with a photoresist pattern, and then an ion implantation process is performed to implant dopants with the second conductivity type, for example, phosphorus or arsenic, into the fins F1 and F2 so that the first portions FP1 of the fins F1 and F2 have the second conductivity type, for example, N type. As shown in FIG. 1, the ion implantation region NP only overlaps with the first portions FP1 of the fins F1 and F2, but does not overlap with the second portions FP2 of the fins F1 and F2. According to an embodiment of the present invention, the doping concentration of the counter-doping region NR is, for example, 1.5×10¹⁸ atoms/cm³-1.5×10²⁰ atoms/cm³.

According to an embodiment of the present invention, the counter-doping region NR has the dopants with the second conductive type, for example, N-type dopants. According to an embodiment of the present invention, the counter-doping region NR can be used as the bottom electrode plate of the MOS capacitor.

According to an embodiment of the present invention, the second portions FP2 of the fins F1 and F2 may be implanted with dopants of the second conductivity type, such as phosphorus or arsenic. In other words, the second portions FP2 of the fins F1 and F2 also have the second conductivity type. The first portions FP1 and the second portions FP2 of the fins F1 and F2 may have the same conductivity type.

The first portions FP1 of the fins F1 and F2 formed with the counter-doping region NR have a cross-sectional profile similar to a pointed cone shape, while the second portions FP2 have a cross-sectional profile similar to a rectangle shape that is beneficial because the quality of the epitaxial layer formed on the second portions FP2 of the fins F1 and F2 during the subsequent processing can be improved.

According to an embodiment of the present invention, the semiconductor device 1 further includes a gate G extending above the fins F1 and F2 along a second direction D2. According to an embodiment of the present invention, the gate G is surrounded by the dielectric layer 110. According to an embodiment of the present invention, the gate G overlaps the first portions FP1 of the fins F1 and F2. According to an embodiment of the present invention, the gate G does not overlap with the second portions FP2 of the fins F1 and F2. According to an embodiment of the present invention, the gate G is, for example, a metal gate. For example, the metal gate can be formed using a replacement metal gate (RMG) process, and its detailed structure will not be described herein for the sake of simplicity.

According to an embodiment of the present invention, the semiconductor device 1 further includes an insulating layer GOX, which is disposed between the first portions FP1 of the fins F1 and F2 and the gate G, which functions as a capacitor insulating layer. The gate G, the first portion FP1 and the insulating layer GOX constitute a metal-oxide-semiconductor capacitor C.

According to an embodiment of the invention, each of the second portions FP2 of the fins F1 and F2 includes an epitaxial layer EP. According to an embodiment of the present invention, the epitaxial layer EP includes a SiP epitaxial layer. According to an embodiment of the present invention, the epitaxial layer EP is contiguous with the counter-doping region NR in the first portions FP1 of the fins F1 and F2.

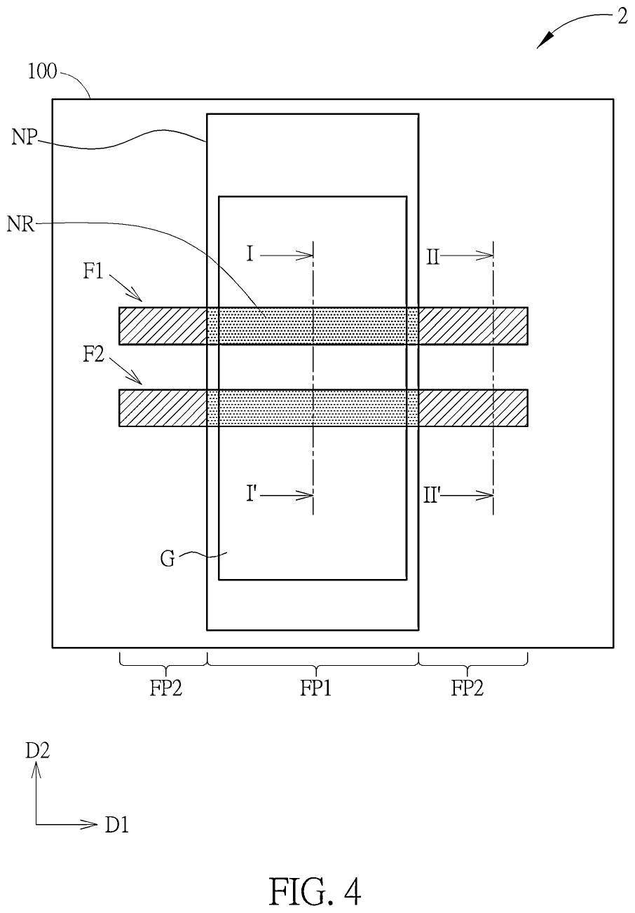

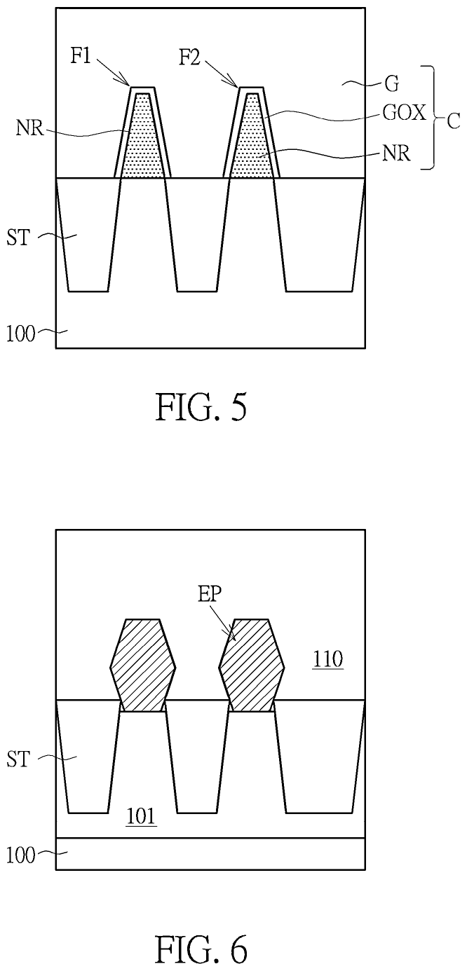

Please refer to FIG. 4 to FIG. 6, wherein FIG. 4 is a top view of a semiconductor device according to an embodiment of the present invention, FIG. 5 is a schematic cross-sectional view taken along line I-I′ in FIG. 4, and FIG. 6 is a schematic cross-sectional view taken along line II-II′ in FIG. 4. As shown in FIG. 4 to FIG. 6, likewise, the semiconductor device 2, such as a metal-oxide-semiconductor capacitor, includes a semiconductor substrate 100 and has a first conductivity type. According to an embodiment of the present invention, the semiconductor substrate 100 may be, for example, a silicon substrate, but is not limited thereto. According to embodiments of the present invention, the first conductivity type may be, for example, P type.

According to an embodiment of the present invention, a well region 101 may be provided in the semiconductor substrate 100, wherein the well region 101 has a first conductivity type. According to embodiments of the present invention, the well region 101 may be, for example, a P-type well. According to embodiments of the present invention, for example, the semiconductor device 2 may be disposed within an NMOS transistor device region. Those familiar with this technical field should understand that there will be other semiconductor elements in the NMOS transistor device region, such as fin field effect transistors. For the sake of simplicity, these semiconductor elements are not shown in the figures.

According to an embodiment of the present invention, at least one fin, such as fins F1 and F2, is provided on the semiconductor substrate 100 in the well region 101, wherein the fins F1 and F2 extend along the first direction D1. According to an embodiment of the present invention, the fins F1 and F2 protrude from the top surface of the trench isolation structure ST. According to an embodiment of the present invention, each of the fins F1 and F2 includes a first portion FP1 and a second portion FP2 that is contiguous with the first portion FP1. According to an embodiment of the present invention, only the second portions FP2 of the fins F1 and F2 are located on the well region 101 (for example, a P-type well). Directly below the first portion FP1 of the fins F1 and F2 is the semiconductor substrate 100, and the well region 101 does not extend into the area directly below the first portion FP1 of the fins F1 and F2.

According to an embodiment of the present invention, likewise, the first portion FP1 includes a counter-doping region NR. According to an embodiment of the present invention, the counter-doping region NR is formed before forming the fins F1 and F2. An ion implantation region NP is first defined with a photoresist pattern, and then an ion implantation process is performed to implant dopants with the second conductivity type, for example, phosphorus or arsenic, into the fins F1 and F2 so that the first portions FP1 of the fins F1 and F2 have the second conductivity type, for example, N type. As shown in FIG. 4, the ion implantation region NP only overlaps with the first portions FP1 of the fins F1 and F2, but does not overlap with the second portions FP2 of the fins F1 and F2. According to an embodiment of the present invention, the doping concentration of the counter-doping region NR is, for example, 1.5×10¹⁸ atoms/cm³-1.5×10²⁰ atoms/cm³. Since the semiconductor substrate 100 is directly under the first portion FP1 of the fins F1 and F2 instead of the P-type well, the doping concentration of the counter-doping region NR can be reduced and the cross-sectional profiles of the fins F1 and F2 can be improved.

According to an embodiment of the present invention, the counter-doping region NR has dopants of the second conductive type, for example, N-type dopants. According to an embodiment of the present invention, the counter-doping region NR can be used as the bottom electrode plate of the MOS capacitor.

According to an embodiment of the present invention, the second portions FP2 of the fins F1 and F2 may be implanted with dopants of the second conductivity type, such as phosphorus or arsenic. In other words, the second portions FP2 of the fins F1 and F2 may have the second conductivity type. The first portions FP1 and the second portions FP2 of the fins F1 and F2 have the same conductivity type.

The first portions FP1 of the fins F1 and F2 formed with the counter-doping region NR have a cross-sectional profile similar to a pointed cone shape, while the second portions FP2 have a cross-sectional profile similar to a rectangle shape that is beneficial because the quality of the epitaxial layer formed on the second portions FP2 of the fins F1 and F2 during the subsequent processing can be improved.

According to an embodiment of the present invention, the semiconductor device 2 further includes a gate G extending above the fins F1 and F2 along the second direction D2. According to an embodiment of the present invention, the gate G is surrounded by the dielectric layer 110. According to an embodiment of the present invention, the gate G overlaps the first portions FP1 of the fins F1 and F2. According to an embodiment of the present invention, the gate G does not overlap with the second portions FP2 of the fins F1 and F2. According to an embodiment of the present invention, the gate G is, for example, a metal gate. For example, the metal gate can be formed using a replacement metal gate process, and its detailed structure will not be described herein for the sake of simplicity.

According to an embodiment of the present invention, the semiconductor device 2 further includes an insulating layer GOX, which is disposed between the first portions FP1 of the fins F1 and F2 and the gate G, which can function as a capacitor insulating layer. The gate G, the first portion FP1 and the insulating layer GOX constitute a metal-oxide-semiconductor capacitor C.

According to an embodiment of the invention, the second portions FP2 of the fins F1 and F2 may include an epitaxial layer EP. According to an embodiment of the present invention, the epitaxial layer EP includes a SiP epitaxial layer. According to an embodiment of the present invention, the epitaxial layer EP is contiguous with the counter-doping region NR in the first portions FP1 of the fins F1 and F2.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A semiconductor device, comprising:
a semiconductor substrate having a first conductivity type;
a well region having the first conductivity type in the semiconductor substrate;
a fin disposed on the semiconductor substrate within the well region, wherein the fin extends along a first direction, wherein the fin comprises a first portion and a second portion that is contiguous with the first portion, wherein the first portion comprises a counter-doping region having dopants of a second conductivity type; and
a gate extending over the fin along a second direction, wherein the gate overlaps with the first portion of the fin and does not overlap with the second portion of the fin.

2. The semiconductor device according to claim 1 further comprising:
an insulating layer disposed between the first portion of the fin and the gate, wherein the gate, the first portion, and the insulating layer constitute a metal-oxide-semiconductor capacitor.

3. The semiconductor device according to claim 1, wherein the second portion of the fin does not include the dopants of the second conductivity type.

4. The semiconductor device according to claim 1, wherein the first conductivity type is P type and the second conductivity type is N type.

5. The semiconductor device according to claim 1, wherein the well region is a P well region, and wherein the first portion of the fin and the second portion of the fin are above the P well region.

6. The semiconductor device according to claim 1, wherein the second portion of the fin comprises an epitaxial layer.

7. The semiconductor device according to claim 6, wherein the epitaxial layer comprises a SiP epitaxial layer.

8. The semiconductor device according to claim 6, wherein the epitaxial layer is contiguous with the counter-doping region in the first portion of the fin.

9. The semiconductor device according to claim 1, wherein the gate is a metal gate.

10. The semiconductor device according to claim 1, wherein the counter-doping region has a doping concentration of 1.5×10¹⁸-1.5×10²⁰ atoms/cm³.

11. A semiconductor device, comprising:
a semiconductor substrate having a first conductivity type;
a fin disposed on the semiconductor substrate, wherein the fin extends along a first direction, wherein the fin comprises a first portion and a second portion that is contiguous with the first portion, wherein the first portion comprises a counter-doping region having dopants of a second conductivity type; and
a gate extending over the fin along a second direction, wherein the gate overlaps with the first portion of the fin and does not overlap with the second portion of the fin.

12. The semiconductor device according to claim 11 further comprising:
an insulating layer disposed between the first portion of the fin and the gate, wherein the gate, the first portion, and the insulating layer constitute a metal-oxide-semiconductor capacitor.

13. The semiconductor device according to claim 11, wherein the second portion of the fin does not include the dopants of the second conductivity type.

14. The semiconductor device according to claim 11, wherein the first conductivity type is P type and the second conductivity type is N type.

15. The semiconductor device according to claim 11, wherein the fin is surrounded by a trench isolation structure, and wherein the first portion of the fin and the second portion of the fin are above the trench isolation structure.

16. The semiconductor device according to claim 11, wherein the second portion of the fin comprises an epitaxial layer.

17. The semiconductor device according to claim 16, wherein the epitaxial layer comprises a SiP epitaxial layer.

18. The semiconductor device according to claim 16, wherein the epitaxial layer is contiguous with the counter-doping region in the first portion of the fin.

19. The semiconductor device according to claim 11, wherein the gate is a metal gate.

20. The semiconductor device according to claim 11, wherein the counter-doping region has a doping concentration of 1.5×10¹⁸-1.5×10²⁰ atoms/cm³.
